(19) United States
(12) Patent Application Publication
(10) Pub. No.: US 2026/0190366 A1
(43) Pub. Date: Jul. 2, 2026

(54) 2D SEMICONDUCTOR DEVICE AND FABRICATION METHOD THEREFOR

(71) Applicant: NANJING UNIVERSITY, Jiangsu (CN)

(72) Inventors: Maguang ZHU, Jiangsu (CN); Yan BAI, Jiangsu (CN); Lingyu ZHANG, Jiangsu (CN); Yifu SUN, Jiangsu (CN); Kaiyue HE, Jiangsu (CN)

(73) Assignee: NANJING UNIVERSITY, Jiangsu (CN)

(21) Appl. No.: 19/417,289

(22) Filed: Dec. 11, 2025

Related U.S. Application Data
(63) Continuation of application No. PCT/CN2025/100369, filed on Jun. 11, 2025.

(30) Foreign Application Priority Data
Dec. 30, 2024 (CN) 202411967551.5

(51) Int. Cl. H10D 30/01; H10D 30/47

(52) U.S. Cl. CPC H10D 30/017; H10D 30/481

(57) ABSTRACT

The present disclosure discloses a 2D semiconductor device and a fabrication method therefor. The device includes a substrate, a two-dimensional (2D) semiconductor material layer, and a gate structure including a gate dielectric layer and a gate electrode layer, where the gate dielectric layer includes a portion covered by a bottom of the gate electrode layer and portions not covered by the bottom of the gate electrode layer, and the portions not covered by the bottom of the gate electrode layer extend outward along the 2D semiconductor material layer; the portions of the gate dielectric layer not covered by the bottom of the gate electrode layer and both sides of the gate electrode layer are covered with spacers; support layers are disposed on surfaces of the spacers; and source and drain metal contact layers vertically penetrate through the support layers, the spacers, the 2D semiconductor material layer, and the substrate.

### CROSS-REFERENCE TO RELATED APPLICATION

This application is a continuation of international application of PCT application serial no. PCT/CN 2025/100369, filed on Jun. 11, 2025, which claims the priority benefit of China application no. 202411967551.5, filed on Dec. 30, 2024. The entirety of each of the above-mentioned patent applications is hereby incorporated by reference herein and made a part of this specification.

### TECHNICAL FIELD

The present disclosure relates to a semiconductor device and a fabrication method therefor, and in particular to a 2D semiconductor device and a fabrication method therefor.

### BACKGROUND

With continuous development of a semiconductor technology, advanced silicon-based integrated circuit devices are pushing toward a 2 nm process node. However, as process nodes continue to shrink, Moore's Law is gradually losing validity in the semiconductor industry. A silicon-based integrated circuit technology is facing bottlenecks in process costs, physical limits, and yield. Especially as a device size continues to scale down, trade-offs between power consumption, performance, and cost in a conventional silicon-based technology become more complex and difficult. Therefore, the semiconductor industry urgently requires new materials and processing techniques to drive continuous technological advancement. Two-dimensional (2D) materials, with unique physical properties, have become highly promising candidates in the post-Moore era, and are capable of effectively replacing conventional silicon materials and solving many problems in the current integrated circuit technology.

The 2D materials, such as molybdenum disulfide (MoS₂), have excellent subthreshold swing characteristics and a high electron mobility, thereby having broad application prospects in future electronic devices. However, a conventional dry etching process technology has significant shortcomings in etching depth control, sidewall verticality, and etching rate selectivity. Especially when processing the 2D materials, it is difficult for an etching method in the prior art to achieve high-precision control, which is prone to causing material damage or non-uniform etching, thereby affecting the final performance of a device. In addition, because the 2D materials are extremely thin, a doping technique in the prior art usually causes damage to a channel, and a new method for doping is required.

Therefore, there is an urgent need for an improved technological process that reduces damage to materials and improves device yield.

### SUMMARY

Objectives: A first objective of the present disclosure is to provide a 2D semiconductor device capable of improving the overall performance, yield, and reliability of a device.

A second objective of the present disclosure is to provide a fabrication method for the above 2D semiconductor device.

Technical solution: The 2D semiconductor device of the present disclosure includes a substrate, a 2D semiconductor material layer disposed on the substrate, and a gate structure disposed on the 2D semiconductor material layer, the gate structure including a gate dielectric layer and a gate electrode layer above the gate dielectric layer, where the gate dielectric layer includes a portion covered by a bottom of the gate electrode layer and portions not covered by the bottom of the gate electrode layer, and the portions not covered by the bottom of the gate electrode layer extend outward along a surface of the 2D semiconductor material layer, respectively; the portions of the gate dielectric layer not covered by the bottom of the gate electrode layer and both sides of the gate electrode layer are covered with spacers; support layers made of a low dielectric constant material are disposed on surfaces of the spacers; and tops of the support layers, the spacers, and the gate electrode layer are coplanar, and source and drain metal contact layers vertically penetrate through the support layers, the spacers located on a surface of the gate dielectric layer, the 2D semiconductor material layer, and the substrate.

The fabrication method for the above 2D semiconductor device includes the following steps:
(A) forming a 2D semiconductor material layer on a substrate, depositing a yttrium metal layer on the 2D semiconductor material layer, and annealing the yttrium metal layer in an inert atmosphere to achieve yttrium sulfide metallization; and after annealing, removing the yttrium metal layer, and retaining yttrium metal seeds;
(B) forming a gate dielectric layer on a surface of the 2D semiconductor material layer with the retained yttrium metal seeds, and forming a gate electrode layer on a surface of the gate dielectric layer to obtain a gate structure;
(C) patterning a source region and a drain region by photolithography, etching away the gate electrode layers in the source region and the drain region, etching the gate dielectric layer downward to a predetermined depth, and then forming spacers on exposed surfaces;
(D) depositing a low dielectric constant (low-k) material on surfaces of the spacers to form support layers for a source metal and a drain metal;
(E) planarizing the structure obtained in the step (D) by chemical mechanical polishing (CMP), stopping at the gate electrode layer, and removing excess portions of the support layers to expose the gate electrode layer;
(F) etching the remaining portions of the support layers downward to form recesses extending into the substrate; and
(G) depositing the source metal and the drain metal into the recesses to form ohmic contacts with the 2D semiconductor material layer; and after deposition, removing excess metals to expose the gate structure to obtain the 2D semiconductor device.

Further, in the step (A), the yttrium metal layer is deposited through electron beam evaporation under a high vacuum environment, and a deposition thickness of the yttrium metal layer is 1-2 nm.

Further, in the step (A), a mixed gas of argon and hydrogen is used in the annealing process to prevent oxidation and enhance an activity of the seeds.

Further, in the step (A), an annealing temperature is 240-300° C., and an annealing duration is 20-40 min.

Further, in the step (A), the yttrium metal layer is removed by acid etching, and the yttrium metal seeds are retained.

Further, in the step (A), prior to depositing the yttrium metal layer, patterned local contact regions are treated with low-power argon soft plasma or electron beam irradiation to perform surface modification of the 2D semiconductor material and generate active sites.

Further, in the step (A), the 2D material is MoS₂; and prior to depositing the yttrium metal layer, a MoS₂ surface is bombarded with low-power soft plasma to induce sulfur vacancies on the MoS₂ surface, with a bombardment duration of 5 s-30 s, and a concentration controlled within a range of 5%-20%.

Further, in the step (G), a deposition temperature is 200-250° C.

Further, after the step (G), residual photoresist or hard mask materials are removed, and the device is encapsulated.

Beneficial effects: Compared with the prior art, the present disclosure achieves the following significant effects:
(1) By depositing the yttrium metal layer on the 2D semiconductor material layer, subsequently cleaning the yttrium metal layer away to leave the yttrium seeds, doping the 2D material with the yttrium metal for the source region and the drain region, and employing the yttrium metal as the seeds to obtain a high-performance gate structure, the present disclosure achieves a significant decrease in a subthreshold swing and a contact resistance of the device, an effective suppression on short-channel effects, and a reduction in channel defects, thereby markedly enhancing the overall performance, yield, and reliability of the device. (2) By forming the recesses via etching vertically through the support layers, the spacers located on the surface of the gate dielectric layer, the 2D semiconductor material layer, and the substrate, and allowing the recesses to extend into the substrate layer, the present disclosure achieves an effective protection of the 2D channel material through technological process, and solves the problem of an etching stop depth for the 2D material. (3) The process is compatible with a silicon-based process in the prior art and suitable for mass production. Compared with a conventional silicon-based field-effect transistor, the present disclosure maintains excellent electrical performance at a smaller geometric scale, and thus exhibits superior performance in a high-density integrated circuit. (4) The present disclosure is applicable to a field-effect transistor based on 2D materials (such as molybdenum disulfide or carbon nanotubes). The device may be applied in a high-performance, low-power integrated circuit, flexible electronic device, sensor, and next-generation computing and communication equipment.

### BRIEF DESCRIPTION OF THE DRAWINGS

FIG. 1 is a schematic structural view of a 2D semiconductor device according to the present disclosure.

FIG. 2 is a schematic flow chart of a fabrication method for a 2D semiconductor device according to the present disclosure.

FIG. 3 illustrates a performance comparison between a 2D semiconductor device of the present disclosure and a 2D semiconductor device obtained without any treatment on a surface of a 2D semiconductor material layer.

### DESCRIPTION OF THE EMBODIMENTS

The present disclosure will be described in further detail below.

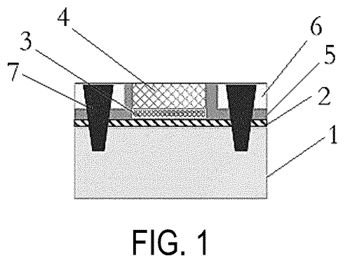

As shown in FIG. 1, the present disclosure provides a 2D semiconductor device, including a substrate 1, a 2D semiconductor material layer 2 disposed on the substrate 1, and a gate structure disposed on the 2D semiconductor material layer 2, the gate structure including a gate dielectric layer 3 and a gate electrode layer 4 above the gate dielectric layer 3, where the gate dielectric layer 3 includes a portion covered by a bottom of the gate electrode layer and portions not covered by the bottom of the gate electrode layer, and the portions not covered by the bottom of the gate electrode layer extend outward along a surface of the 2D semiconductor material layer 2, respectively; the portions of the gate dielectric layer 3 not covered by the bottom of the gate electrode layer and both sides of the gate electrode layer are covered with spacers 5; support layers 6 made of a low dielectric constant material are disposed on surfaces of the spacers 5; and tops of the support layers 6, the spacers 5, and the gate electrode layer are coplanar, and source and drain metal contact layers 7 vertically penetrate through the support layers 6, the spacers 5 located on a surface of the gate dielectric layer 3, the 2D semiconductor material layer 2, and the substrate 1.

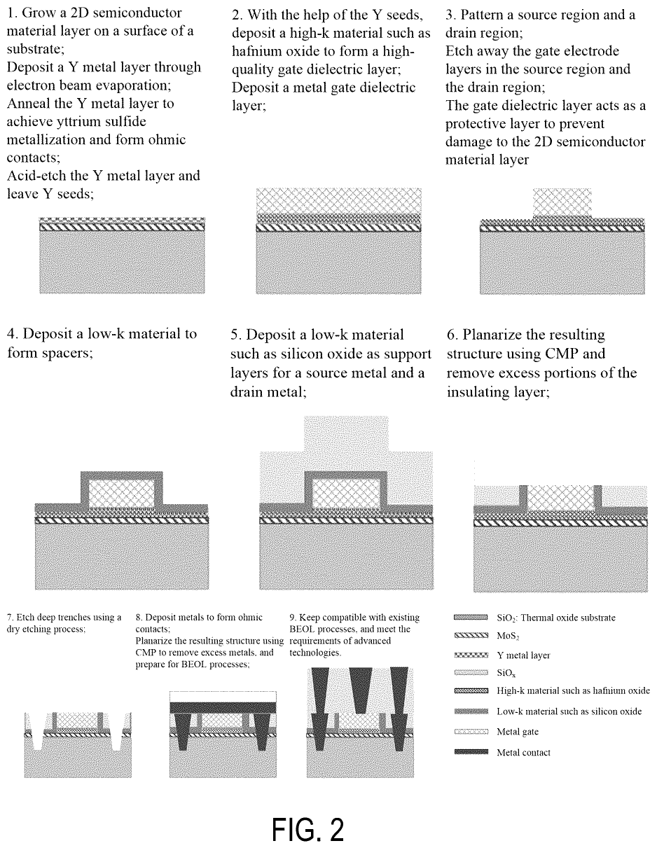

A fabrication method for the above 2D semiconductor device, as shown in FIG. 2, includes the following steps:

### 1. Material Stacking and Layer Structure Preparation

(1) First, a 2D semiconductor material layer 2 is grown on a silicon oxide substrate 1 through a chemical vapor deposition (CVD) method. In this embodiment, the 2D semiconductor material is molybdenum disulfide (MoS₂), with a thickness of 1-5 nm. The CVD method may be replaced by a physical vapor deposition (PVD) method, a mechanical transfer method, or the like.
(2) Patterned local contact regions are treated with low-power argon soft plasma to modify a contact interface and generate active sites. This low-power soft plasma filters high-energy particles to induce a tiny amount of sulfur vacancies on a surface of the top-layer MoS₂ without damaging an overall lattice of the 2D MoS₂. In an experiment, as the bombardment time increases, a concentration of the sulfur vacancy defects increases, and a crystal structure is gradually damaged. Therefore, it is necessary to reasonably control the concentration of the sulfur vacancy defects to achieve optimal doping. In this embodiment, a bombardment power is 30 W, and a bombardment duration is 20 s.
(3) A yttrium (Y) metal layer is deposited on a surface of the 2D semiconductor material layer 2 through electron beam evaporation under a high vacuum environment. A deposition thickness of the yttrium metal layer is maintained between 1 nm and 2 nm, and a deposition rate is maintained at 0.3 A/s. A mixed gas of argon and hydrogen is used in the annealing process to prevent oxidation and enhance an activity of the seeds.
(4) Yttrium sulfide metallization is performed at a temperature of 240° C. under an inert gas atmosphere to reduce defect formation and ensure the uniformity and quality of the 2D semiconductor material layer, so as to form effective ohmic contacts.
(5) Subsequently, the yttrium metal layer is removed by acid etching, and the seeds are retained. After being deposited, the yttrium metal layer is removed by dilute hydrochloric acid. This process may simultaneously remove some contaminants from a channel surface.

To further optimize the deposition of the yttrium seeds, a deposition thickness and uniformity of the yttrium metal layer are controlled to ensure the subsequent growth of a high-quality top gate layer. In the annealing process, the temperature and atmosphere are appropriately adjusted to promote the uniform distribution of the yttrium metal layer, reduce interface defects, and enhance a strength of bonding between the top gate layer and the 2D semiconductor material layer. A duration of the acid etching for removing the yttrium metal layer also needs to be adjusted according to the deposition thickness of the yttrium metal layer.

### 2. Deposition of a Gate Dielectric Layer 3 and a Metal Gate Electrode Layer 4 to Form a Gate Structure

(1) With the help of the yttrium seeds, a high dielectric constant material, i.e., a high-k material, is deposited by an atomic layer deposition (ALD) method to form a gate dielectric layer 3. The gate dielectric layer 3 reduces defects occurring between a channel and an insulating layer. A precursor, tetrakis(ethylmethylamido)hafnium (TEMAH), is used in conjunction with an oxidizer, O₃, for the deposition. A deposition temperature is controlled at 250° C. to achieve atomic-level thickness control, ensure uniform coverage, and reduce leakage current. This ALD method belongs to the prior art. The precursor may be replaced by hafnium chloride (HfCl₄), and the oxidizer may be replaced by H₂O.
(2) A metal gate is deposited on a surface of the gate dielectric layer 3 to form a gate stack dielectric layer, i.e., a gate structure.

### 3. Formation of a Metal Gate Electrode Layer

A source region and a drain region are patterned on the resulting structure by photolithography. Subsequently, the metal gate electrode layers and portions of the gate dielectric layer 3 in the source region and the drain region are removed by a dry etching process. The gate dielectric layer 3 acts as a protective layer in this process to prevent damage to the 2D semiconductor material layer. A plasma-enhanced reactive ion etching (RIE) method is used in the etching process, and a gas flow rate and a radio frequency power are controlled to achieve high selectivity etching and reduce damage to the 2D material.

### 4. Deposition of Spacers

A low dielectric constant material, i.e., a low-k material, is deposited on exposed surfaces of a structure obtained in the step 3 to form spacer 5 structures. This step helps reduce a parasitic capacitance and improve a switching speed and an electrical performance of the device. A thickness of the deposited low-k material should be controlled within an appropriate range to ensure a mechanical strength and an electrical isolation effect of the spacers 5.

### 5. Deposition of Support Layers

Silicon oxide is deposited on the source region and the drain region to form support layers 6 for a source metal and a drain metal, so as to prevent collapse during subsequent metal deposition. A CVD method may be employed for the deposition of the silicon oxide, and a thickness is controlled between 20 nm and 30 nm to achieve effective isolation without compromising the scalability of the device. The silicon oxide may be replaced by other low-k dielectric materials.

### 6. Polishing to the Metal Gate Electrode Layer by CMP

The entire structure is planarized by CMP, and excess portions of the support layers 6 are removed to ensure a consistent flatness of the source metal region and the drain metal region, so as to improve the accuracy of the subsequent deposition process. In the CMP process, a soft pad is employed and a polishing speed is optimized to reduce damage to the sensitive layer, ensure planarization effects, and enhance manufacturing yield.

### 7. Trench Formation and Source/Drain Metal Deposition

Deep trenches are formed through the isolation layers along both sides of the gate electrode layer by a dry etching process. Specifically, the support layers 6, the spacers 5 located on a surface of the gate dielectric layer 3, the 2D semiconductor material layer 2, and the substrate 1 are vertically etched to form recesses, to facilitate the deposition of the source metal and the drain metal; and these recesses are of an inverted trapezoidal structure. As the 2D semiconductor material layer is extremely thin, controlling an etching depth is challenging. Therefore, etching proceeds into the substrate 1 layer to achieve an edge contact. In the etching process, real-time etching monitoring, such as optical emission spectroscopy (OES), is employed to precisely control the etching depth, reduce the impact of over-etching on the 2D material, and consequently improve the yield of the device.

### 8. Metal Deposition to Form Ohmic Contacts

The source metal and the drain metal are deposited in the trench regions to form favorable ohmic contacts with the 2D semiconductor material layer. The specific deposition method belongs to the prior art. For example, PVD may be used; and a deposition temperature is controlled between 200° C. and 250° C., and a gas flow rate is precisely controlled to ensure the uniformity and denseness of the metal film. After metal deposition is completed, excess metals are removed through photolithography and dry etching processes to ensure that the metal remains only in the source region and the drain region, reduce a parasitic resistance, and improve the switching performance.

The material for the source and drain metal contact layers 7 belongs to the prior art. Specifically, the material may be a single-layer or multi-layer metal or metal compound material, such as any stacked combination of Ti, Al, TiN, Ta, TaN, TiAl, TiAlN, TiAlSc, AlSc, TiSc, TiPd, and AlPd; and a thickness of the material is determined according to the requirements of the device.

### 9. Post-Treatment

After etching, residual photoresist or hard mask materials need to be removed, and an oxygen plasma cleaning technique is employed to remove these residues. The oxygen plasma is capable of effectively removing organic photoresist residues to ensure the smooth progression of subsequent processes.

### 10. Encapsulation

Finally, the device is encapsulated to ensure a mechanical strength and an electrical stability. An encapsulation material may be silicon oxide or polyimide to ensure an isolation effect of the device from an environment and to provide mechanical support. This step ensures the compatibility of the device with other components in back-end-of-line (BEOL) processes, and meets the integration requirements of advanced technologies.

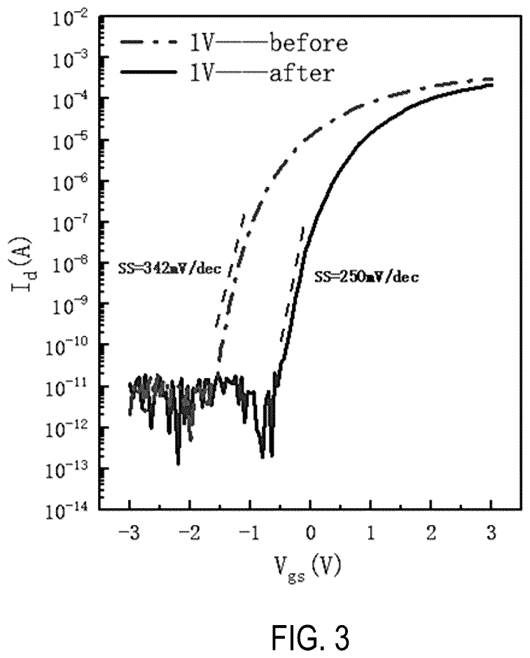

As shown in FIG. 3, “after” represents a 2D semiconductor-based field-effect transistor obtained by the method of the present disclosure, whereas “before” represents a 2D semiconductor-based field-effect transistor fabricated by omitting the steps (2) to (5) in the above step 1 of the present disclosure, with the surface of the 2D semiconductor material layer untreated. A comparison between the two demonstrates a significant improvement in the subthreshold swing of the 2D semiconductor-based field-effect transistor of the present disclosure.

What is claimed is:

1. A 2D semiconductor device, comprising a substrate, a two-dimensional (2D) semiconductor material layer disposed on the substrate, and a gate structure disposed on the 2D semiconductor material layer, the gate structure comprising a gate dielectric layer and a gate electrode layer above the gate dielectric layer, wherein the gate dielectric layer comprises a portion covered by a bottom of the gate electrode layer and portions not covered by the bottom of the gate electrode layer, and the portions not covered by the bottom of the gate electrode layer extend outward along a surface of the 2D semiconductor material layer, respectively; the portions of the gate dielectric layer not covered by the bottom of the gate electrode layer and both sides of the gate electrode layer are covered with spacers; support layers made of a low dielectric constant material are disposed on surfaces of the spacers; and tops of the support layers, the spacers, and the gate electrode layer are coplanar, and source and drain metal contact layers vertically penetrate through the support layers, the spacers located on a surface of the gate dielectric layer, the 2D semiconductor material layer, and the substrate.

2. A fabrication method for the 2D semiconductor device of claim 1, comprising the following steps:
(A) forming a 2D semiconductor material layer on a substrate, depositing a yttrium metal layer on the 2D semiconductor material layer, and annealing the yttrium metal layer in an inert atmosphere to achieve yttrium sulfide metallization; and after annealing, removing the yttrium metal layer, and retaining yttrium metal seeds;
(B) forming a gate dielectric layer on a surface of the 2D semiconductor material layer with the retained yttrium metal seeds, and forming a gate electrode layer on a surface of the gate dielectric layer to obtain a gate structure;
(C) patterning a source region and a drain region using photolithography, etching away the gate electrode layers in the source region and the drain region, etching the gate dielectric layer downward to a predetermined depth, and forming spacers on exposed surfaces;
(D) depositing a low dielectric constant material on surfaces of the spacers to form support layers for a source metal and a drain metal;
(E) planarizing the structure obtained in the step (D) using chemical mechanical polishing (CMP), stopping at the gate electrode layer, and removing excess portions of the support layers to expose the gate electrode layer;
(F) etching the remaining portions of the support layers downward to form recesses extending into the substrate; and
(G) depositing the source metal and the drain metal into the recesses to form ohmic contacts with the 2D semiconductor material layer; and after deposition, removing excess metals to expose the gate structure to obtain the 2D semiconductor device.

3. The fabrication method for the 2D semiconductor device according to claim 2, wherein in the step (A), the yttrium metal layer is deposited through electron beam evaporation under a high vacuum environment, and a deposition thickness of the yttrium metal layer is 1-2 nm.

4. The fabrication method for the 2D semiconductor device according to claim 2, wherein in the step (A), a mixed gas of argon and hydrogen is used in the annealing process to prevent oxidation and enhance an activity of the seeds.

5. The fabrication method for the 2D semiconductor device according to claim 2, wherein in the step (A), an annealing temperature is 240-300° C., and an annealing duration is 20-40 min.

6. The fabrication method for the 2D semiconductor device according to claim 2, wherein in the step (A), the yttrium metal layer is removed by acid etching, and the yttrium metal seeds are retained.

7. The fabrication method for the 2D semiconductor device according to claim 2, wherein in the step (A), prior to depositing the yttrium metal layer, patterned local contact regions are treated with low-power argon soft plasma or electron beam irradiation to perform surface modification of the 2D semiconductor material and generate active sites.

8. The fabrication method for the 2D semiconductor device according to claim 2, wherein in the step (A), the 2D material is MoS₂; and prior to depositing the yttrium metal layer, a MoS₂ surface is bombarded with low-power soft plasma to induce sulfur vacancies on the MoS₂ surface, with a bombardment duration of 5 s-30 s, and a concentration controlled within a range of 5%-20%.

9. The fabrication method for the 2D semiconductor device according to claim 2, wherein in the step (G), a deposition temperature is 200-250° C..

10. The fabrication method for the 2D semiconductor device according to claim 2, wherein after the step (G), residual photoresist or hard mask materials are removed, and the 2D semiconductor device is encapsulated.
